(19) United States
(12) Patent Application Publication
(10) Pub. No.: US 2026/0047065 A1
(43) Pub. Date: Feb. 12, 2026

(54) DRAM CELL FABRICATION APPROACHES FOR DOPED MOLD

(71) Applicant: Applied Materials, Inc., Santa Clara, CA (US)

(72) Inventors: Chang Seok Kang, Santa Clara, CA (US); Ruiying Hao, San Jose, CA (US); Raghuveer S. Makala, Campbell, CA (US); Amy Lynn Child, Gansevoort, NY (US); Fredrick Fishburn, Los Gatos, CA (US); Hoi-Sung Chung, Sunnyvale, CA (US); Zhijun Chen, San Jose, CA (US); Balasubramanian Pranatharthiharan, San Jose, CA (US)

(73) Assignee: Applied Materials, Inc., Santa Clara, CA (US)

(21) Appl. No.: 18/795,651

(22) Filed: Aug. 6, 2024

(51) Int. Cl. H10B 12/00

(52) U.S. Cl. CPC H10B 12/05; H10B 12/03; H10B 12/482; H10B 12/488

(57) ABSTRACT

Approaches for forming 3D DRAM cells are disclosed. One method may include forming a dielectric liner and a fill material within a plurality of lateral openings extending from a slot, wherein the plurality of lateral openings and the slot are formed in a carbon-doped stack of alternating first layers and second layers, and partially removing the dielectric liner from the plurality of lateral openings. The method may further include forming a sacrificial layer along the plurality of lateral openings and the slot, removing the sacrificial layer, and forming a gate dielectric along the plurality of lateral openings and the slot following removal of the sacrificial layer.

### FIELD OF THE DISCLOSURE

The present embodiments relate to dynamic random-access memory (DRAM) processing and, more particularly, to incorporating a sacrificial layer during DRAM processing to mitigate the effects of carbon doped molds.

### BACKGROUND OF THE DISCLOSURE

DRAM provides advantages of structural simplicity, low cost, and high speed in comparison to alternative types of memory. For 3D DRAM, a plurality of alternating epitaxial layers may be used as a mold to realize crystalline channels. In some cases, the alternating epitaxial layers include silicon (Si) and silicon germanium (SiGe), wherein Si and SiGe are used as a channel and sacrificial layer, respectively. However, multiple layers of Si/SiGe are prone to crystalline defects resulting from lattice mismatch between Si and SiGe. Carbon incorporation into Si or SiGe is one approach used to reduce mechanical stress caused by the lattice mismatch. However, carbon incorporation into the channel has its own drawbacks, namely, degraded dielectric quality.

Accordingly, improved approaches are needed for DRAM cell fabrication.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include forming a sacrificial layer within a plurality of lateral openings and a slot of a carbon-doped stack of alternating first layers and second layers, wherein the sacrificial layer is formed along exposed surfaces of the first layers. the method may further include removing the sacrificial layer, and forming a gate dielectric along the plurality of lateral openings and the slot following removal of the sacrificial layer.

In another aspect, a method of forming a dynamic-random-access-memory cell may include forming a sacrificial layer within a plurality of lateral openings and a slot of a carbon-doped stack of alternating first layers and second layers, wherein the sacrificial layer is formed along exposed surfaces of the first layers. the method may further include removing the sacrificial layer, and forming a gate dielectric along the plurality of lateral openings and the slot following removal of the sacrificial layer.

In yet another aspect, a method of forming a gate dielectric in a dynamic-random-access-memory device may include forming a sacrificial layer within a plurality of lateral openings and a slot of a stack of alternating first layers and carbon-doped second layers, wherein the sacrificial layer is formed by thermally oxidizing one or more exposed surfaces of the first layers within the plurality of lateral openings and the slot. The method may further include removing the sacrificial layer, and forming a gate dielectric along the plurality of lateral openings and the slot following removal of the sacrificial layer.

### BRIEF DESCRIPTION OF THE DRAWINGS

The accompanying drawings illustrate exemplary approaches of the disclosure, including the practical application of the principles thereof, as follows:

FIG. 1 is a schematic top-view diagram of an example multi-chamber processing system, in accordance with one or more embodiments of the present disclosure;

FIG. 2 depicts a cross-sectional view of a stack of first and second layers of a DRAM device, in accordance with one or more embodiments of the present disclosure;

FIG. 3 depicts a cross-sectional view of the DRAM device following formation of a first plurality of lateral openings, in accordance with one or more embodiments of the present disclosure;

FIG. 4 depicts a cross-sectional view of the DRAM device following formation of a dielectric liner and a fill material within the lateral openings and along a slot, in accordance with one or more embodiments of the present disclosure;

FIG. 5 depicts a cross-sectional view of the DRAM device following partial removal of the dielectric liner, in accordance with one or more embodiments of the present disclosure;

FIG. 6 depicts a cross-sectional view of the DRAM device following formation of a sacrificial layer within the slot and the lateral openings, in accordance with one or more embodiments of the present disclosure;

FIG. 7 depicts a cross-sectional view of the DRAM device following removal of the sacrificial layer within the slot and the lateral openings, in accordance with one or more embodiments of the present disclosure;

FIG. 8 depicts a cross-sectional view of the DRAM device including a gate dielectric formed along the lateral openings and the slot following removal of the sacrificial layer, in accordance with one or more embodiments of the present disclosure;

FIG. 9 depicts a cross-sectional view of the DRAM device during a wordline formation process, in accordance with one or more embodiments of the present disclosure;

FIG. 10 depicts a cross-sectional view of the DRAM device following formation of a dielectric within the slot and a set of recesses on opposite sides of the slot, in accordance with one or more embodiments of the present disclosure;

FIG. 11 depicts a cross-sectional view of the DRAM device following formation of a slit along an exterior of the stack, in accordance with one or more embodiments of the present disclosure;

FIG. 12 depicts a cross-sectional view of the DRAM device after trimming of the first layers, in accordance with one or more embodiments of the present disclosure;

FIG. 13 depicts a cross-sectional view of the DRAM device following formation of a dielectric liner and fill material, in accordance with one or more embodiments of the present disclosure;

FIG. 14 depicts a cross-sectional view of the DRAM device following further trimming of the first layers, in accordance with one or more embodiments of the present disclosure;

FIG. 15 depicts a cross-sectional view of the DRAM device following formation of a high-K dielectric and a top electrode, in accordance with one or more embodiments of the present disclosure; and

FIGS. 16-17 depict cross-sectional views of the DRAM device following formation of a barrier metal and bitline fill, in accordance with one or more embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

Carbon incorporation into Si channel of 3D DRAM degrades characteristics of gate dielectric quality. Embodiments of the present disclosure disclose 3D DRAM cell structures and integration schemes that mitigate the effects of carbon in carbon-incorporated Si and SiGe molds by using a sacrificial layer to increase interface quality of the channel.

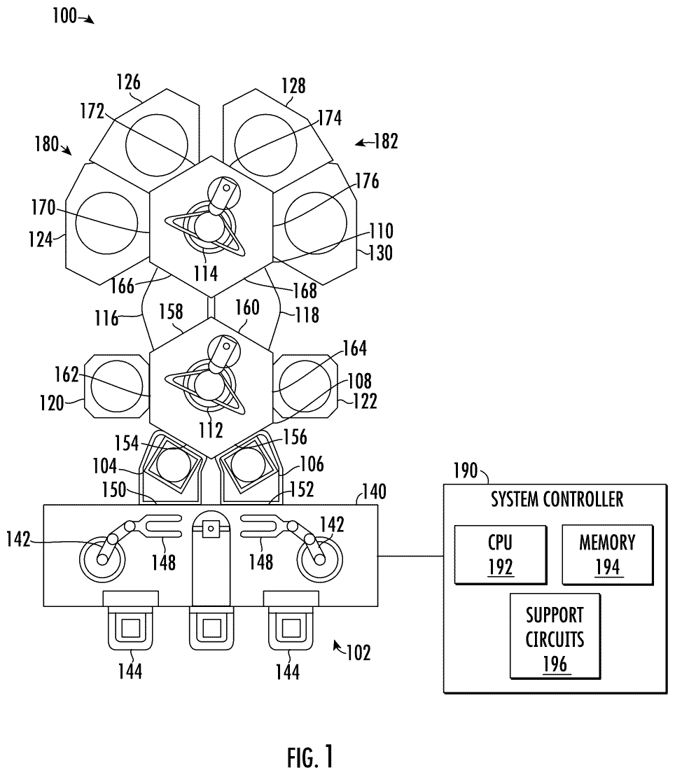

FIG. 1 is a schematic top-view diagram of an example of a multi-chamber processing system 100 according to some examples of the present disclosure. Although non-limiting, the processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. Wafers in the processing system 100 can be processed in and transferred between the various chambers without exposing the wafers to an ambient environment exterior to the processing system 100 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 100. Accordingly, the processing system 100 may provide for an integrated solution for some processing of wafers.

Examples of a processing system that may be suitably modified in accordance with the teachings provided herein include the Endura®, Producer® or Centura® integrated processing systems or other suitable processing systems commercially available from Applied Materials, Inc., located in Santa Clara, Calif. It is contemplated that other processing systems (including those from other manufacturers) may be adapted to benefit from aspects described herein.

In the illustrated example of FIG. 1, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130.

The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some examples, the processing chamber 122 can be capable of performing a cleaning process, the processing chamber 120 can be capable of performing an etch process, and the processing chambers 124, 126, 128, 130 can be capable of performing respective epitaxial growth processes. The processing chamber 122 may be a SiCoNi™ Preclean chamber available from Applied Materials of Santa Clara, Calif. The processing chamber 120 may be a Selectra™ Etch chamber available from Applied Materials of Santa Clara, Calif. Embodiments herein are not limited in this context, however.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, and 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general-purpose processor that can be used in an industrial setting. The memory 194, or non-transitory computer-readable medium, is accessible by the CPU 192 and may be one or more of memory such as random-access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

FIG. 2 demonstrates a mold of a DRAM device (hereinafter “device”) 200 during processing. As shown, the device 200 may include a stack of layers 202, such as alternating first layers 204 and second layers 206 formed atop a base layer 207. A mask 205 may be formed over the alternating first layers 204 and second layers 206. In some embodiments, the first layers 204 may be silicon (Si) and the second layers 206 may be silicon germanium (SiGe), which may be doped with carbon (C). For example, Ge in the second layers 206 may be approximately 1-50%, while the C in the second layers 206 may be approximately 0.1-5%. In other embodiments, the first layers 204 may be carbon-doped. Although non-limiting, each of the first layers 204 and the second layers 206 may have a thickness between approximately 10-70nm. The thicknesses of the first layers 204 and the second layers 206 may vary based upon the design of a given memory structure.

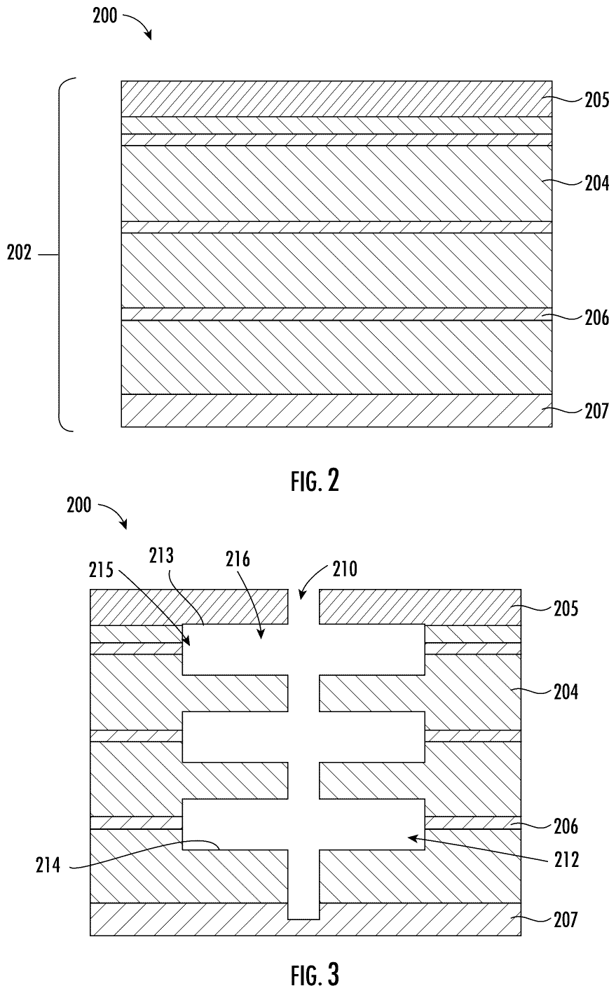

As shown in FIG. 3, the stack of layers 202 may be processed by forming a slot 210 vertically through the alternating first layers 204 and second layers 206, and then recessing the second layers 206. The slot 210 may be formed into vertical wordlines, horizontal bitlines, capacitors, and the like, and may be formed, for example, by using a mask and etching process that etches both the c-Si and c-SiGe of the first layers 204 and the second layers 206, respectively. In some embodiments, the SiGe of the second layers 206 is removed horizontally using a selective dry or wet etch. In some embodiments, the second layers 206 may be trimmed using a selective removal process (SRP) to target only the SiGe. By adjusting the selective removal process, the amount of lateral etching may be precisely controlled.

The first layers 204 may then be trimmed to form a plurality of lateral openings 212. As shown, each of the lateral openings 212 may be defined by an upper surface 213, a lower surface 214, a first end 215, and a second end 216. In some embodiments, the lateral openings 212 may be formed using a tetramethylammoniumhydroxide (TMAH) aqueous solution, which recesses the Si of the first layers 204. The second layers 206 may act as a lateral etch stop.

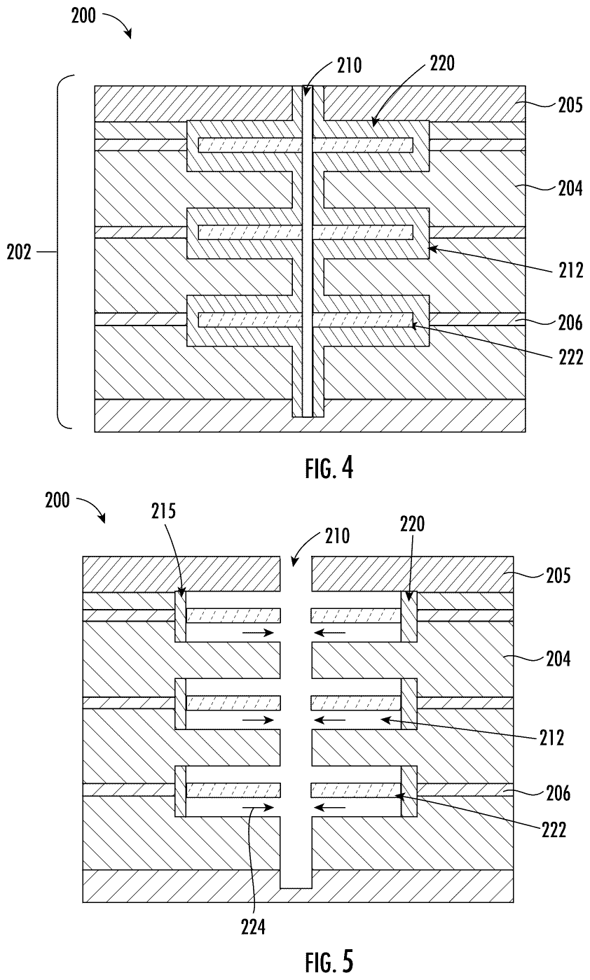

As shown in FIG. 4, a dielectric liner 220 and a fill material 222 may be formed within the lateral openings 212 and along the slot 210. In some embodiments, the dielectric liner 220 is a conformal silicon nitride (SiN) formed using atomic layer deposition (ALD) to a thickness of approximately 5-30nm. The fill material 222 may be silicon oxide (SiO) formed using ALD to a thickness of approximately 5-30nm. After deposition, the fill material 222 may be removed from the slot 210.

As shown in FIG. 5, the dielectric liner 220 may be partially removed using, for example, a hot phosphoric acid aqueous solution 224. A portion of the dielectric liner 220 may remain along the first end 215 of each lateral opening 212. As shown, the hot phosphoric acid aqueous solution 224 is selective to the fill material 222.

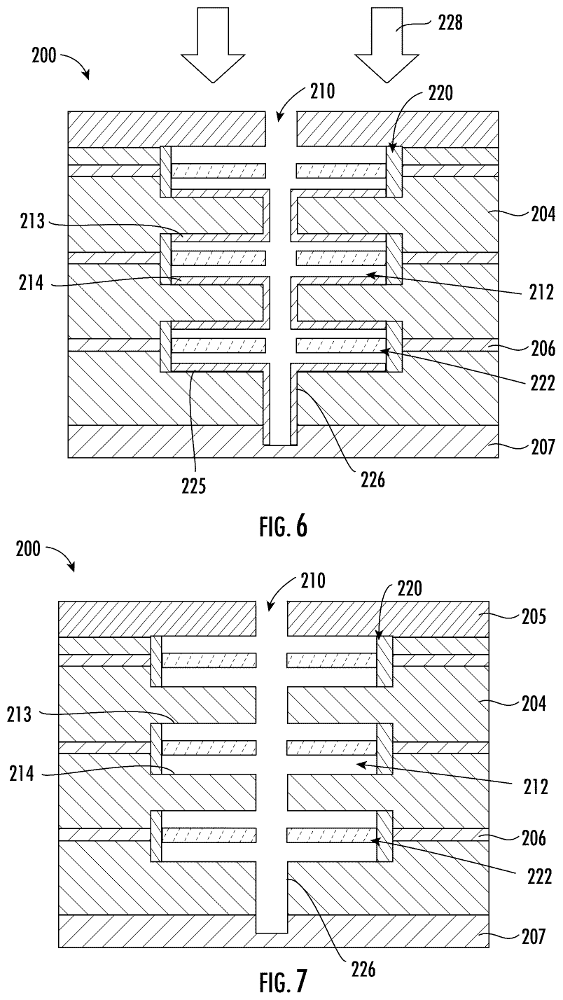

As shown in FIG. 6, a sacrificial layer 225 may then be formed within the slot 210 and the lateral openings 212. In some embodiments, the sacrificial layer 225 may be a silicon layer (e.g., SiO, SiON, or SiN) formed by thermal oxidation, the sacrificial layer 225 being formed along exposed surfaces of the first layers 204. More specifically, the sacrificial layer 225 may be formed along the upper and lower surfaces 213, 214 of the lateral openings 212 and along an inner surface 226 of the slot 210. However, the sacrificial layer 225 is generally not formed directly over the dielectric liner 220 at the first end 215 of each lateral opening 212 or along the fill material 222. In some embodiments, the sacrificial layer 225 may extend partially into the base layer 207. Advantageously, when growing the sacrificial layer 225 (e.g., SiO(N)) on Si first layers 204 including carbon, carbon tends to move into SiO or Si/SiO interface from the Si first layers 204. Therefore, gate dielectrics subsequently grown on Si first layers 204 after removing the sacrificial layer 225 have negligible carbon concentration. As a result, gate dielectric quality can be maintained.

In some embodiments, the sacrificial layer 225 may receive an optional plasma treatment 228, e.g., N2, Ar, O2, H2, NH3, NO2, or N2O, which is performed at a temperature ranging from 400°-1000°C. The plasma treatment 228 enhances carbon diffusion into the ambient from the silicon channel. Carbon diffused out from the silicon into the silicon substrate reacts with gases in the ambient. Thus, the quality of the subsequently formed gate dielectric can be improved due to the reduction in carbon concentration in the gate dielectric.

The sacrificial layer 225 may then be removed, as shown in FIG. 7. In some embodiments, the sacrificial layer 225 may be exposed to hydrofluoric (HF) acid, which removes the sacrificial layer 225 from the upper and lower surfaces 213, 214 of the lateral openings 212 and from the inner surface 226 of the slot 210.

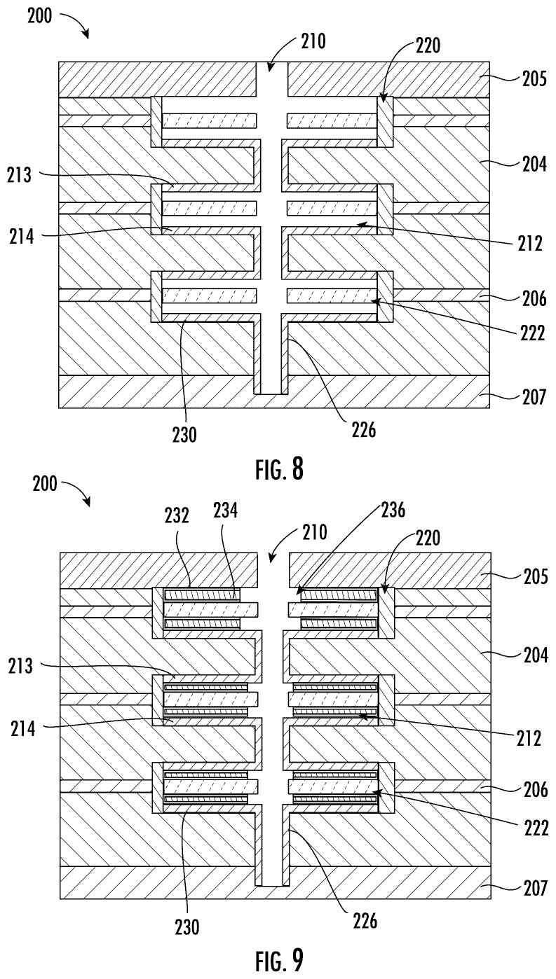

As shown in FIG. 8, a gate dielectric 230 may then be formed along the lateral openings 212 and the slot 210 following removal of the sacrificial layer 225. In some embodiments, the gate dielectric 230 is a gate oxide layer, which is grown (e.g., by thermal oxidation) or deposited using an ALD process via the slot 210. More specifically, the gate dielectric 230 is formed on the upper and lower surfaces 213, 214 of the lateral openings 212 and along the inner surface 226 of the slot 210. Although non-limiting, the gate dielectric 230 may have a thickness or approximately 1-5 nm.

As shown in FIG. 9, a wordline process is then performed in which a first conformal layer 232, e.g., titanium nitride (TiN) is formed over the exposed surfaces within the lateral openings 212 and along the slot 210, including over the gate dielectric 230 and the fill material 222. A second layer 234, e.g., tungsten (W), may then be deposited over the first conformal layer 232, and the first conformal layer 232 and the second layer 234 may be etched back from the slot 210 to form a set of recesses 236 on opposite sides of the fill material 222. Although non-limiting, the first conformal layer 232 may have a thickness of approximately 1-5 nm and the second layer 234 may have a thickness of approximately 2-20 nm.

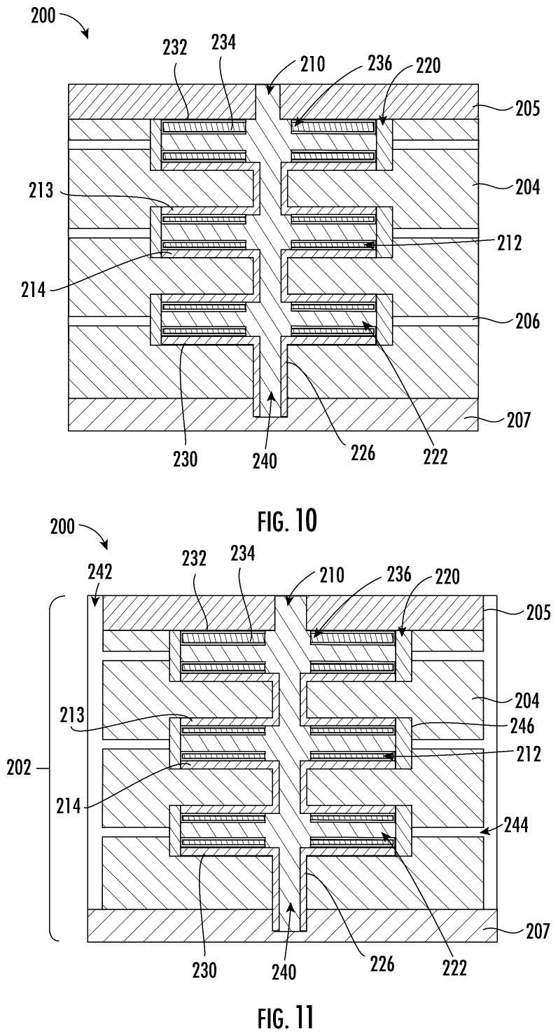

As shown in FIG. 10, a dielectric 240 (e.g., SiO2) may then be deposited within the slot 210 and the set of recesses 236 on opposite sides of the slot 210, and a slit 242 may be formed (e.g., etched) along an exterior of the stack of layers 202, as shown in FIG. 11. The second layers 206 may also be removed to form a second plurality of lateral openings 244 between the first layers 204. In this embodiment, the second plurality of lateral openings 244 extend to an exterior 246 of the dielectric liner 220 within the lateral openings 212.

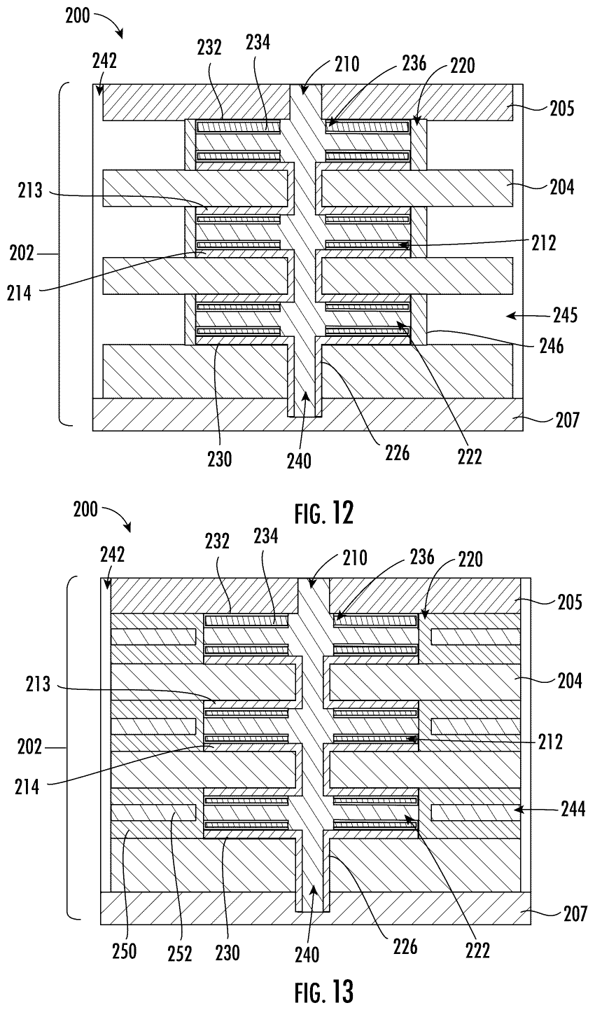

As shown in FIG. 12, the first layers 204 may be trimmed via the slit 242 and the second plurality of lateral openings 244 to form a plurality of exterior lateral openings 245. In various embodiments, the exterior lateral openings 245 may be formed via a wet or dry etch process. As shown, the etch process is selective to the exterior 246 of the dielectric liner 220. A second dielectric liner 250 may then be formed within the exterior lateral openings 245, followed by a second fill material 252 over the second dielectric liner 250, as shown in FIG. 13. In some embodiments, the second dielectric liner 250 is a conformal layer of nitride (e.g., SiN) formed to a thickness of approximately 5-30 nm via ALD, and the second fill material 252 is an oxide (e.g., SiO) formed to a thickness of approximately 5-30 nm via ALD.

As shown in FIG. 14, the first layers 204 may be recessed by exhuming Si from the slit 242 (e.g., using TMAH) to form a third plurality of lateral openings 248, and a source/drain (S/D) 254 may be formed along the exposed surfaces of the remaining portions of the second layers 206. In some embodiments, the S/D 254 may be a N+S/D, which is formed using gas phase doping (e.g., PH3) at a temperature of 500°-900°C.

A bottom electrode 256 may then be formed over the S/D 254 and over the second dielectric liner 250. In some embodiments, the bottom electrode 256 may be TiN, which is conformally deposited within each of the third plurality of lateral openings 248.

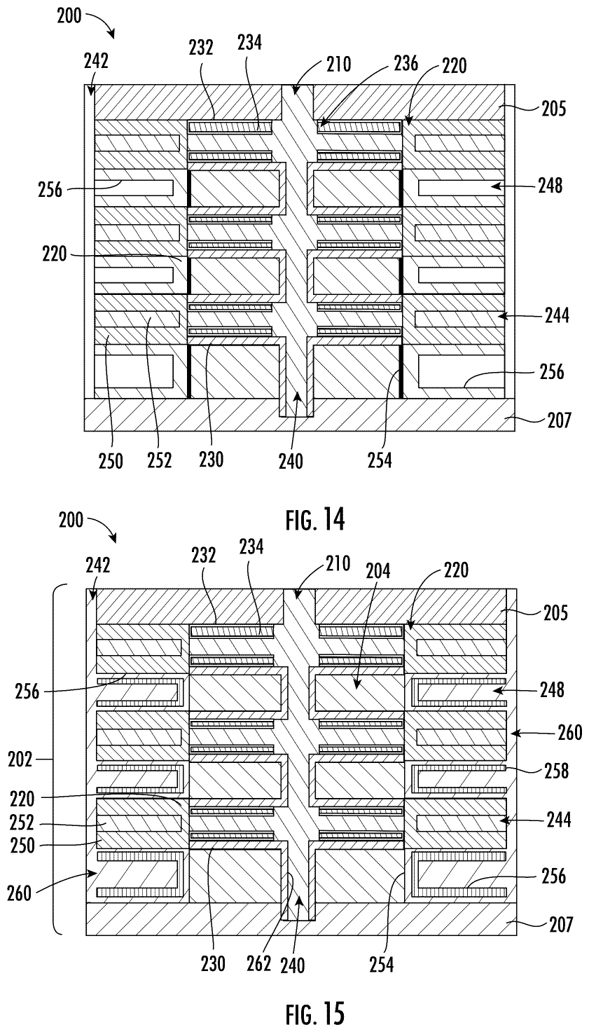

As shown in FIG. 15, a high-K dielectric 258 (e.g., HfZrO) may be formed over the bottom electrode 256 within the third plurality of lateral openings 248, and then a top electrode 260 may be formed by depositing TiN within the slits 242. As shown, the top electrode 260 may be further formed over the high-K dielectric 258 within each of the third plurality of lateral openings 248. The slot 210 may then be reopened to pattern a vertical bitline through the stack of layers 202, and a second, bitline S/D 262 may be formed along surfaces of the first layers 204 exposed within the slot 210. In some embodiments, the bitline S/D 262 may be a N+S/D, which is formed using gas phase doping (e.g., PH3) at a temperature of 500°-900°C.

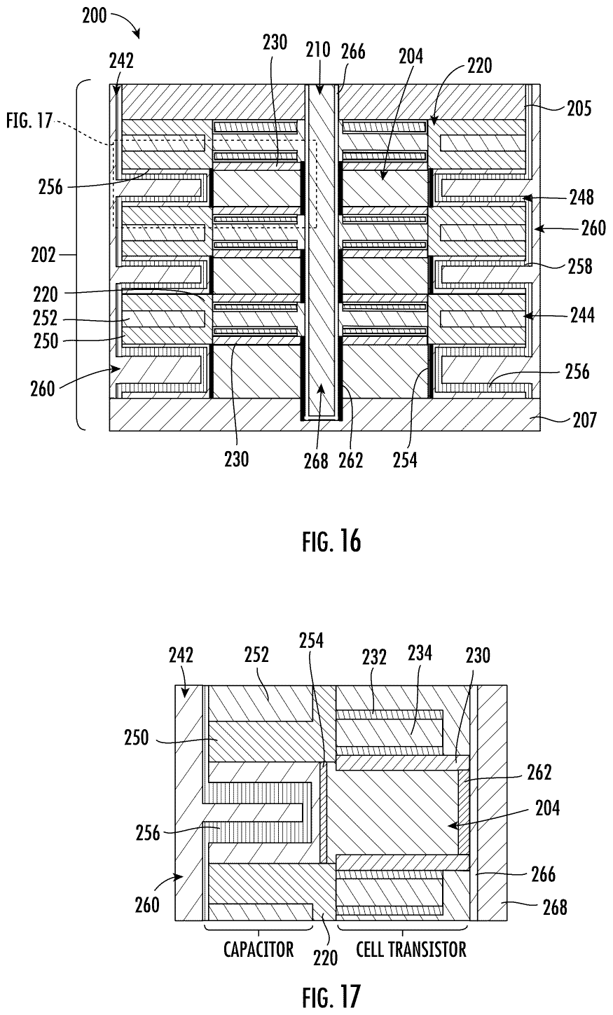

As shown in FIGS. 16-17, a barrier metal 266 may be formed within the slot 210, followed by a bitline fill 268 over the barrier metal 266. In some embodiments, the barrier metal 266 may be TiN and the bitline fill 268 may be W. Other metals are possible in alternative examples. FIG. 17 further demonstrates formation of the capacitor feature and the cell transistor of the device 200, which in this example may be a 3D DRAM.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art.

For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
forming a sacrificial layer within a plurality of lateral openings and a slot of a carbon-doped stack of alternating first layers and second layers, wherein the sacrificial layer is formed along exposed surfaces of the first layers;
removing the sacrificial layer; and
forming a gate dielectric along the plurality of lateral openings and the slot following removal of the sacrificial layer.

2. The method of claim 1, wherein the sacrificial layer is formed along the exposed surfaces of the first layers using a thermal oxidation process.

3. The method of claim 2, further comprising performing a plasma treatment following formation of the sacrificial layer, wherein the plasma treatment is performed at a temperature between 400°C. and 1000°C.

4. The method of claim 1, further comprising:
forming a dielectric liner and a fill material within the plurality of lateral openings; and
partially removing the dielectric liner from the plurality of lateral openings, wherein the sacrificial layer is formed along the exposed surfaces of the first layers after the dielectric liner is partially removed from the plurality of lateral openings.

5. The method of claim 4, wherein partially removing the dielectric liner from the plurality of lateral openings comprises performing a wet etch to remove the dielectric liner from the slot and from an upper surface and a bottom surface of each of the plurality of lateral openings, and wherein the dielectric liner remains along a first end of each of plurality of lateral openings.

6. The method of claim 1, wherein forming the gate dielectric along the plurality of lateral openings and the slot comprises performing a thermal oxidation process to form a gate oxide along the plurality of lateral openings and the slot.

7. The method of claim 1, further comprising forming a wordline following formation of the gate dielectric.

8. The method of claim 1, further comprising:
partially recessing the first layers;
forming a first source/drain along a first side of one or more of the first layers;
forming a bottom electrode over the first source/drain;
forming a top electrode over the bottom electrode;
forming a second source/drain along a second side of the one or more of the first layers; and
forming a bitline in the slot following formation of the second source/drain.

9. A method of forming a dynamic-random-access-memory device, the method comprising:
forming a sacrificial layer within a plurality of lateral openings and a slot of a stack of alternating first layers and carbon-doped second layers, wherein the sacrificial layer is formed along one or more exposed surfaces of the first layers;
removing the sacrificial layer;
forming a gate dielectric along the plurality of lateral openings and the slot following removal of the sacrificial layer.

10. The method of claim 9, wherein the sacrificial layer is formed along the one or more exposed surfaces of the first layers using a thermal oxidation process.

11. The method of claim 10, further comprising performing a plasma treatment following formation of the sacrificial layer, wherein the plasma treatment is performed at a temperature between 400°C. and 1000°C.

12. The method of claim 9, further comprising:
forming a dielectric liner and a fill material within the plurality of lateral openings; and
partially removing the dielectric liner from the plurality of lateral openings, wherein the sacrificial layer is formed along the exposed surfaces of the first layers after the dielectric liner is partially removed from the plurality of lateral openings.

13. The method of claim 12, wherein partially removing the dielectric liner from the plurality of lateral openings comprises performing a wet etch to remove the dielectric liner from the slot and from an upper surface and a bottom surface of each of the plurality of lateral openings, and wherein the dielectric liner remains along a first end of each of plurality of lateral openings.

14. The method of claim 9, wherein forming the gate dielectric along the plurality of lateral openings and the slot comprises performing a thermal oxidation process to form an oxide along the plurality of lateral openings and the slot.

15. The method of claim 9, further comprising:
partially recessing the first layers;
forming a first source/drain along a first side of one or more of the first layers;
forming a bottom electrode over the first source/drain;
forming a top electrode over the bottom electrode;
forming a second source/drain along a second side of the one or more of the first layers; and
forming a bitline in the slot following formation of the second source/drain.

16. A method of forming a gate dielectric in a dynamic-random-access-memory device, the method comprising:
forming a sacrificial layer within a plurality of lateral openings and a slot of a stack of alternating first layers and carbon-doped second layers, wherein the sacrificial layer is formed by thermally oxidizing one or more exposed surfaces of the first layers within the plurality of lateral openings and the slot;
removing the sacrificial layer; and
forming a gate dielectric along the plurality of lateral openings and the slot following removal of the sacrificial layer.

17. The method of claim 16, further comprising performing a plasma treatment following formation of the sacrificial layer, wherein the plasma treatment is performed at a temperature between 400°C. and 1000°C.

18. The method of claim 16, wherein forming the gate dielectric along the plurality of lateral openings and the slot comprises thermally oxidizing the one or more exposed surfaces of the first layers within the plurality of lateral openings and the slot.

19. The method of claim 16, further comprising:
partially recessing the first layers;
forming a first source/drain along a first side of one or more of the first layers;
forming a bottom electrode over the first source/drain;
forming a top electrode over the bottom electrode;
forming a second source/drain along a second side of the one or more of the first layers; and
forming a bitline in the slot following formation of the second source/drain.

20. The method of claim 16, further comprising:
forming a dielectric liner and a fill material within the plurality of lateral openings; and
partially removing the dielectric liner from the plurality of lateral openings, wherein the sacrificial layer is formed along the exposed surfaces of the first layers after the dielectric liner is partially removed from the plurality of lateral openings.
